(19) United States
(12) Patent Application Publication
(10) Pub. No.: US 2023/0411196 A1
(43) Pub. Date: Dec. 21, 2023

(54) COMPONENT CARRIER FOR SEMICONDUCTOR MANUFACTURING AND COMPONENT TRANSPORT SYSTEM USING SAME

(71) Applicant: SEMES CO., LTD., Cheonan-si (KR)

(72) Inventor: Jae Won SHIN, Seoul (KR)

(73) Assignee: SEMES CO., LTD., Cheonan-si (KR)

(21) Appl. No.: 18/126,974

(22) Filed: Mar. 27, 2023

(30) Foreign Application Priority Data
Jun. 16, 2022 (KR) 10-2022-0073363

(51) Int. Cl. H01L 21/677; H01L 21/67; H01L 21/683

(52) U.S. Cl. CPC H01L 21/67766; H01L 21/6719; H01L 21/67769; H01L 21/6831

(57) ABSTRACT

Proposed is a component carrier for semiconductor manufacturing and component transport system using the same and, more particularly, to a component carrier for semiconductor manufacturing and component transport system using the same with an improved structure to prevent a ring from being separated from the component carrier for semiconductor manufacturing during a ring transport process by temporarily fixing the ring using vacuum adsorption. The carrier transports components while a lower surface thereof is in contact with a transport hand and an upper surface thereof is in contact with a component for semiconductor manufacturing. The carrier includes a first vacuum hole formed through the upper surface, a second vacuum hole formed through the lower surface, and an air passage provided between the first vacuum hole and the second vacuum hole.

### CROSS REFERENCE TO RELATED APPLICATION

The present application claims priority to Korean Patent Application No. 10-2022-0073363, filed Jun. 16, 2022, the entire contents of which is incorporated by reference herein for all purposes.

### BACKGROUND OF THE INVENTION

### Field of the Invention

The present disclosure relates to a component carrier for semiconductor manufacturing and component transport system using the same and, more particularly, to a component carrier for semiconductor manufacturing and component transport system using the same with an improved structure to prevent a ring from being separated from the component carrier for semiconductor manufacturing during a ring transport process by temporarily fixing the ring using vacuum adsorption.

### Description of the Related Art

In the semiconductor manufacturing process, transport arms are used when transferring wafers from storage areas such as FOUPs to process chambers, or from process chambers to process chambers.

The process system includes a process chamber in which several processes are performed, and gas is sometimes used to etch objects in the process chamber. At this time, a process kit ring covers an object to protect all or part of the object or chamber. For example, an annular edge ring is disposed on the outer diameter of the object to protect the surface of an electrostatic chuck (ESC) supporting the object while the object is being etched.

Like the above-described ring, when a component to be transferred has a shape in which the center thereof is penetrated or the bottom surface thereof is not flat, making it difficult to adsorb and transfer the component by a transport arm, a carrier is used. The carrier is disposed between a component such as a ring and a transport arm to support the component when transferring the component. Yet, since conventional component carriers for semiconductor manufacturing do not include a configuration for temporarily fixing components such as rings, and the components are temporarily fixed only by the frictional force between the component and the carrier, components such as rings may move or escape from the component carrier during the transfer process, which is problematic.

### SUMMARY OF THE INVENTION

Accordingly, the present disclosure has been made keeping in mind the above problems occurring in the related art, and the present disclosure is intended to provide a component carrier for semiconductor manufacturing and component transport system using the same, capable of preemptively preventing the possibility of a component being separated from the component carrier in the process of transferring a component for semiconductor manufacturing, such as a ring.

In order to achieve the above objective, according to an embodiment of the present disclosure, there is provided a component carrier for semiconductor manufacturing that transports components while a lower surface thereof is in contact with a transport hand and an upper surface thereof is in contact with a component for semiconductor manufacturing. The carrier includes: a first vacuum hole formed through the upper surface; a second vacuum hole formed through the lower surface; and an air passage provided between the first vacuum hole and the second vacuum hole.

The carrier may further include: a component support pad configured to include a through hole installed on the upper surface to generate frictional force with component part and communicate with the first vacuum hole.

The first vacuum hole is formed in a portion where the component support pad is installed.

The first vacuum hole is provided in plural, and one second vacuum hole is provided.

The second vacuum hole is provided at a position capable of communicating with a vacuum hole formed in the transport hand.

The air passage may individually connect the second vacuum hole and the first vacuum holes, or may include: a first air passage configured to connect the second vacuum hole and any one of the first vacuum holes; and a second air passage configured to connect all of the first vacuum holes.

In order to achieve the above objective, according to an embodiment of the present disclosure, there is provided a component transport system for semiconductor manufacturing, the system including: a component carrier for semiconductor manufacturing configured to transport a component while in contact with the component; a transport hand configured to contact a lower surface of the component carrier for semiconductor manufacturing; and a transport arm configured to drive the transport hand, wherein the component carrier for semiconductor manufacturing may include: a first vacuum hole formed through an upper surface thereof; a second vacuum hole formed through the lower surface thereof; and an air passage provided between the first vacuum hole and the second vacuum hole.

The component transport system may further include: a component support pad configured to include a through hole installed on the upper surface to generate frictional force with component part and communicate with the first vacuum hole.

The first vacuum hole is formed in a portion where the component support pad is installed.

The first vacuum hole is provided in plural and one second vacuum hole is provided.

The second vacuum hole is provided at a position capable of communicating with a vacuum hole formed in the transport hand.

A friction pad including a through hole having a larger cross-sectional area than the vacuum hole is provided on the upper part of the vacuum hole formed in the transport hand, and the second vacuum hole communicates with the through hole of the friction pad.

In order to achieve the above objective, according to an embodiment of the present disclosure, there is provided a plasma processing facility, including: a process chamber in which plasma treatment is performed on a substrate; and a transport robot configured to transport the substrate to the process chamber, and include a transport hand for supporting the substrate from a bottom and a transport arm for driving the transport hand, wherein the process chamber may include: a housing having a processing space therein; a support unit supporting the substrate in the processing space; a gas supply unit supplying a process gas to the processing space; and a plasma source generating plasma from the process gas, wherein the support unit may include: an electrostatic chuck on which the substrate is placed; and a focus ring provided to surround the substrate placed on the electrostatic chuck, and detachably provided from the electrostatic chuck, wherein the focus ring may be coupled to a component carrier for semiconductor manufacturing and transported by the transport robot, wherein the component carrier for semiconductor manufacturing may be configured such that a lower surface thereof is in contact with the transport hand, and on an upper surface thereof, a ring support pad generating frictional force with the focus ring is installed to come into contact with the focus ring, and may include: a first vacuum hole formed through the upper surface; a second vacuum hole formed through the lower surface; and an air passage provided between the first vacuum hole and the second vacuum hole.

As described above, according to the component carrier for semiconductor manufacturing and component transport system using the same of the present disclosure, the possibility of a component being separated from the component carrier in the process of transferring a component for semiconductor manufacturing, such as a ring, can be preemptively prevented.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a plan view of a ring carrier according to one embodiment of the present disclosure;

FIG. 2 is a bottom view of the ring carrier shown in FIG. 1;

FIGS. 3A and 3B are cross-sectional views illustrating two examples of an air passage of the ring carrier shown in FIG. 1;

FIG. 4 is a plan view of a transport hand;

FIG. 5 is a cross-sectional view of the transport hand shown in FIG. 4;

FIG. 6 is a view illustrating a ring transport system including the ring carrier shown in FIG. 1;

FIG. 7 is a view illustrating a state in which a ring is gripped by a component carrier for semiconductor manufacturing in the ring transport system shown in FIG. 6;

FIG. 8 is a view illustrating another embodiment of the ring carrier;

FIG. 9 is a view illustrating a variant embodiment of the ring carrier;

FIG. 10 is a plasma processing facility to which a component transport system according to the present disclosure is applied; and

FIG. 11 is a process chamber of the plasma processing facility to which a component transport system according to the present disclosure is applied.

### DETAILED DESCRIPTION OF THE INVENTION

Hereinafter, specific details for carrying out the present disclosure will be provided by describing embodiments of the present disclosure with reference to the accompanying drawings.

First, one embodiment of a component carrier for semiconductor manufacturing, which is the first aspect of the present disclosure, will be described.

Hereinafter, in the description of the component carrier for semiconductor manufacturing according to the embodiment, a component for semiconductor manufacturing is a ring. Accordingly, in the following description, components and rings are used interchangeably, for example, a component carrier for semiconductor manufacturing is referred to as a ring carrier and a component support pad is referred to as a ring support pad.

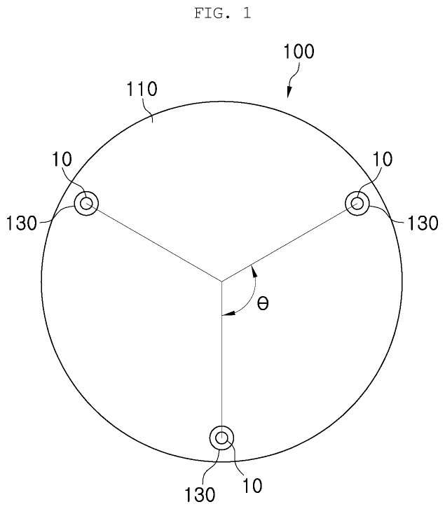

A ring carrier 100 according to the embodiment has a disk shape as shown in FIG. 1. A lower surface 120 of the ring carrier 100 is in contact with a transport hand 200 of a transport arm, and on an upper surface 110 of the ring carrier 100, a ring support pad 130 is installed so that a ring R is transported while being in contact with the ring support pad 130.

Of the two surfaces of the ring carrier 100, the surface in contact with the ring is referred to as the upper surface 110, and the surface in contact with the transport hand is referred to as the lower surface 120.

The ring carrier 100 includes a first vacuum hole 10, a second vacuum hole 20, and an air passage 30.

The first vacuum hole 10 is a hole formed in a portion where the ring support pad 130 is installed, and is provided in plural.

In this embodiment, three first vacuum holes 10 are provided, and a contained angle θ between the pair of first vacuum holes 10 adjacent to the center O of the ring carrier 100 is 120 degrees, which is a value obtained by dividing 360 by N, which is the number of first vacuum holes 10 (which is 3 in this embodiment).

Meanwhile, the first vacuum hole 10 is not necessarily provided in plural. Even if one first vacuum hole 10 is formed, the ring may be fixed by applying downward force to the ring by the adsorption force acting on the first vacuum hole 10. In addition, the frictional force may be defined as the product of the normal force and the coefficient of friction, and as the normal force between the ring support pad 130 and the ring R increases due to the downward force (adsorption force) acting on the ring, the frictional force between the ring support pad 130 and the ring R increases, and thus the effect of preventing separation of the ring R may be expected due to the increased frictional force.

Of course, when there are several first vacuum holes 10, it is clear that there is an advantage in stably supporting the ring compared to a case with one first vacuum hole 10. Thus, in this embodiment, three first vacuum holes 10 are provided.

The ring support pad 130 is a friction member that is in direct contact with the ring R and is disposed on the upper surface 110, and the first vacuum hole 10 is formed in a portion where the ring support pad 130 is installed.

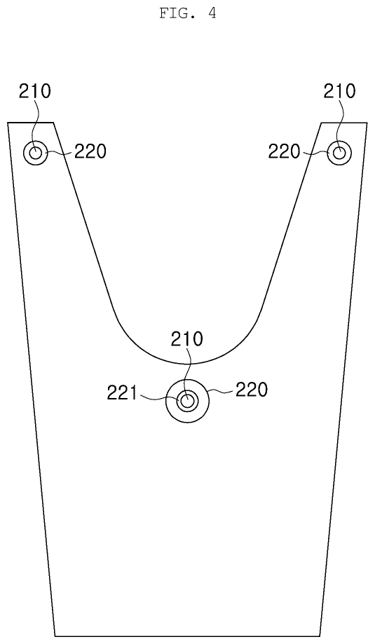

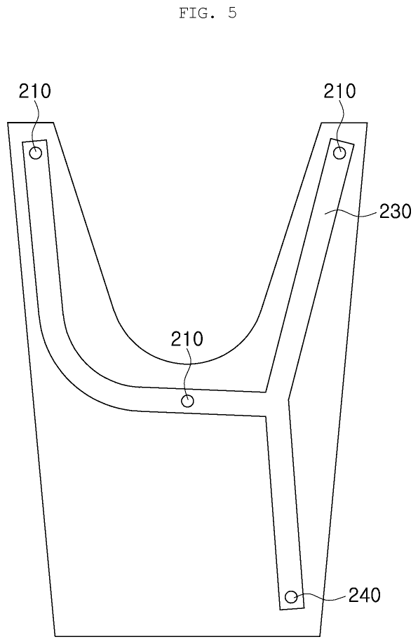

As shown in FIG. 4, the ring support pad 130 is formed with a through hole 131 communicating with the first vacuum hole 10 so that air may flow without clogging.

The position where a component support pad (ring support pad in this embodiment) is installed is determined according to the shape of the component to be supported. When the component is a ring as in the present embodiment, the support pad is installed on the rim of the upper surface 110 according to the shape of the ring and is installed to directly contact the ring. However, when the shape of a component changes, the position of the ring support pad 130 may also change.

On the other hand, the ring carrier 100 and the ring R may be in direct contact without the ring support pad 130.

The second vacuum hole 20 is a hole formed through the lower surface 120 of the ring carrier 100, and is formed at a position capable of communicating with a vacuum hole 210 formed in the transport hand 200. In this embodiment, one second vacuum hole 20 is provided, but several second vacuum holes 20 may be provided.

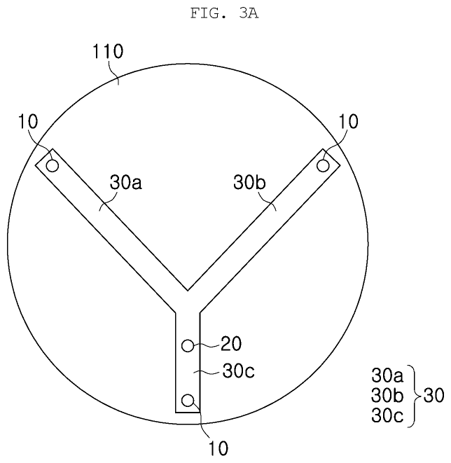

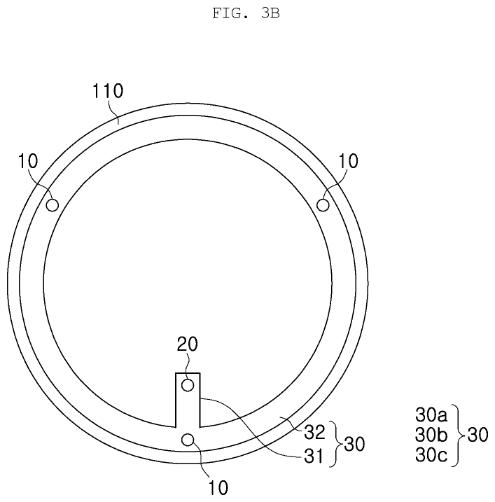

The air passage 30 is a tube connecting the first vacuum hole 10 and the second vacuum hole 20 to each other. The air passage 30 may be composed of tubes 30a, 30b, and 30c connecting the second vacuum hole 20 and the respective first vacuum holes 10 as shown in FIG. 3A, or may include a first air passage 31 connecting the second vacuum hole and any one first vacuum hole and a second air passage 32 formed in a circular shape along the rim of the ring carrier 100 to connect all of the first vacuum holes 10 as shown in FIG. 3B. Unlike the present embodiment, when there is only one first vacuum hole 10, only one tube connecting the first vacuum hole 10 and the second vacuum hole 20 needs to be installed.

When comparing the air passage 30 of the type shown in FIG. 3A and the air passage 30 of the type shown in FIG. 3B, it can be said that the effect is almost the same. Since the length of the air passage is not several meters but several tens of centimeters, there is not a big difference in the distance the air travels by means of a vacuum pump (not shown), and thus almost the same effect occurs in both cases in that the first vacuum hole 10 may adsorb the ring R immediately when the vacuum pump is operated. Nevertheless, the air passage 30 shown in FIG. 3A is characterized by being shorter than the air passage 30 shown in FIG. 3B, whereas in the case of the air passage 30 shown in FIG. 3B, since the air passage 30 is provided over the entire rim of the ring carrier 100, when the first vacuum hole 10 is additionally formed, there is no need to additionally install the air passage 30.

Hereinafter, a mechanism for temporarily fixing the ring R by the ring carrier 100 using the above configuration will be described.

First, the ring carrier 100 is mounted on the upper surface (the surface facing upward) of the transport hand 200. A friction pad 220 including a through hole 221 is installed in the transport hand 200.

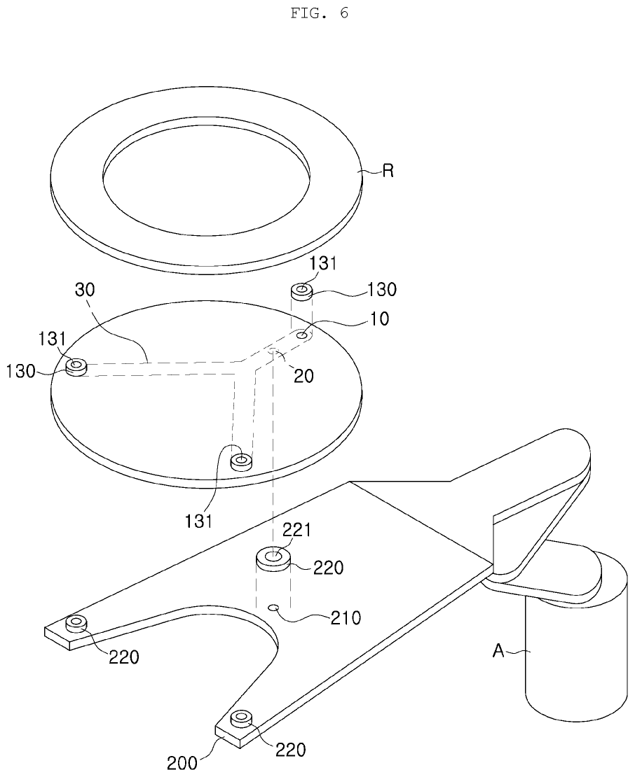

At this time, as shown in FIG. 6, the second vacuum hole 20 of the ring carrier 100 is configured to communicate with any one of the vacuum holes 210 formed in the transport hand 200, and thus an arrangement considering this is required. To make this easier, the friction pad 220 includes the through hole 221 having a cross-sectional area larger than that of the vacuum hole 210, so that when the second vacuum hole 20 is disposed only on top of the through hole 221, air flow may occur. When the cross-sectional area of the through hole 221 is equal to the cross-sectional area of the vacuum hole 210, a very precise arrangement is required because the center of the second vacuum hole 20 and the center of the vacuum hole 210 need to be arranged on a straight line. However, this difficulty may be alleviated by increasing the size of the through hole 221.

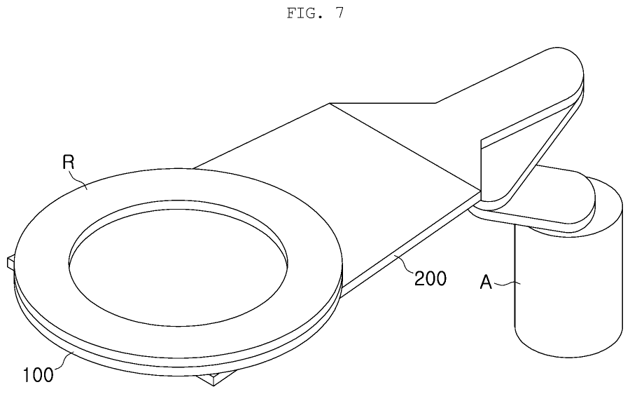

As shown in FIG. 7, when the ring R is disposed on the upper surface of the ring carrier 100, air is sucked in by the vacuum pump, and air flows along the first vacuum holes 10, the air passage 30, the second vacuum hole 20, the through hole 131, the vacuum hole 210 formed through the upper surface of the transport hand, a pipe of the transport hand, the vacuum hole 240 formed through the lower surface of the transport hand, and a pipe (not shown) formed in the transport arm. Due to this air flow, an attractive force acts between the first vacuum hole 10 and the ring R, and by this attractive force, the movement of the ring R is restricted during the transport process of the ring R. In addition, as previously described, the first vacuum hole 10 is formed in a portion where the ring support pad 130 is installed, and an attractive force also acts between the ring R and the ring support pad 130, which acts as a normal force along with gravity acting on the ring R and the ring carrier 100. Accordingly, the frictional force between the ring R and the ring support pad 130 also increases, so that the movement of the ring R is limited by the frictional force.

A component transport system (ring transport system), which is the second aspect of the present disclosure, includes the aforementioned ring carrier 100, the transport hand 200, and a transport arm A.

The ring carrier 100 according to the embodiment has a disk shape as shown in FIG. 1. A lower surface 120 of the ring carrier 100 is in contact with the transport hand 200 of the transport arm, and on an upper surface 110 of the ring carrier 100, a ring support pad 130 is installed so that a ring R is transported while being in contact with the ring support pad 130.

Of the two surfaces of the ring carrier 100, the surface in contact with the ring is referred to as the upper surface 110, and the surface in contact with the transport hand is referred to as the lower surface 120.

The ring carrier 100 includes a first vacuum hole 10, a second vacuum hole 20, and an air passage 30.

The first vacuum hole 10 is a hole formed in a portion where the ring support pad 130 is installed, and is provided in plural.

In this embodiment, three first vacuum holes 10 are provided, and a contained angle θ between the pair of first vacuum holes 10 adjacent to the center O of the ring carrier 100 is 120 degrees, which is a value obtained by dividing 360 by N, which is the number of first vacuum holes 10 (which is 3 in this embodiment).

Meanwhile, the first vacuum hole 10 is not necessarily provided in plural. Even if one first vacuum hole 10 is formed, the ring may be fixed by applying downward force to the ring by the adsorption force acting on the first vacuum hole 10. In addition, the frictional force may be defined as the product of the normal force and the coefficient of friction, and as the normal force between the ring support pad 130 and the ring R increases due to the downward force (adsorption force) acting on the ring, the frictional force between the ring support pad 130 and the ring R increases, and thus the effect of preventing separation of the ring R may be expected due to the increased frictional force.

Of course, when there are several first vacuum holes 10, it is clear that there is an advantage in stably supporting the ring compared to a case with one first vacuum hole 10. Thus, in this embodiment, three first vacuum holes 10 are provided.

The ring support pad 130 is a friction member that is in direct contact with the ring R and is disposed on the upper surface 110, and the first vacuum hole 10 is formed in a portion where the ring support pad 130 is installed.

As shown in FIG. 4, the ring support pad 130 is formed with a through hole 131 communicating with the first vacuum hole 10 so that air may flow without clogging.

The position where a component support pad (ring support pad in this embodiment) is installed is determined according to the shape of the component to be supported. When the component is a ring as in the present embodiment, the support pad is installed on the rim of the upper surface 110 according to the shape of the ring and is installed to directly contact the ring. However, when the shape of a component changes, the position of the ring support pad 130 may also change.

On the other hand, the ring carrier 100 and the ring R may be in direct contact without the ring support pad 130.

The second vacuum hole 20 is a hole formed through the lower surface 120 of the ring carrier 100, and is formed at a position capable of communicating with a vacuum hole 210 formed in the transport hand 200. In this embodiment, one second vacuum hole 20 is provided, but several second vacuum holes 20 may be provided.

The air passage 30 is a tube connecting the first vacuum hole 10 and the second vacuum hole 20 to each other. The air passage 30 may be composed of tubes 30a, 30b, and 30c connecting the second vacuum hole 20 and the respective first vacuum holes 10 as shown in FIG. 3A, or may include a first air passage 31 connecting the second vacuum hole and any one first vacuum hole and a second air passage 32 formed in a circular shape along the rim of the ring carrier 100 to connect all of the first vacuum holes 10 as shown in FIG. 3B. Unlike the present embodiment, when there is only one first vacuum hole 10, only one tube connecting the first vacuum hole 10 and the second vacuum hole 20 needs to be installed.

When comparing the air passage 30 of the type shown in FIG. 3A and the air passage 30 of the type shown in FIG. 3B, the effect is almost the same. Since the length of the air passage 30 is not several meters but several tens of centimeters, there is not a big difference in the distance the air travels by means of a vacuum pump (not shown), and thus almost the same effect occurs in both cases in that the first vacuum hole 10 may adsorb the ring R immediately when the vacuum pump is operated. Nevertheless, the air passage 30 shown in FIG. 3A is characterized by being shorter than the air passage 30 shown in FIG. 3B, whereas in the case of the air passage 30 shown in FIG. 3B, since the air passage 30 is provided over the entire rim of the ring carrier 100, when the first vacuum hole 10 is additionally formed, there is no need to additionally install the air passage 30.

The transport hand 200 contacts the lower surface of the ring carrier 100, and includes the vacuum hole 210 and a friction pad 220.

A through hole 221 is formed in the friction pad 220, and the cross-sectional area of the through hole 221 is larger than that of the vacuum hole 210.

In this way, when the cross-sectional area of the through hole 221 is larger than the cross-sectional area of the vacuum hole 210, the air flow is maintained even if the center of the second through hole 20 of the ring pad 100 and the center of the vacuum hole 210 are not exactly aligned.

The transport arm A is coupled with the transport hand 200 to drive the transport hand 200.

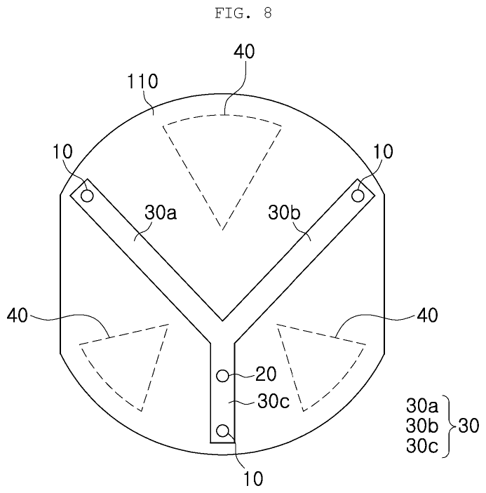

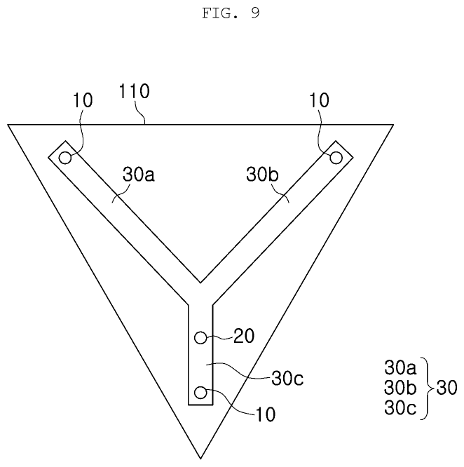

Although the above-described embodiment has been described based on an embodiment in which the ring carrier 100 is provided in a disk shape, the ring carrier 100 is not limited to a specific shape and may be provided in various ways. For example, as shown in FIG. 8, a portion of the disk is formed flat, so that the ring carrier 100 may be easily put down or lifted in another seating position. In addition, as shown in FIG. 8, openings 40 may be formed in parts of the ring carrier 100 to reduce the weight of the ring carrier 100. As shown in FIG. 9, the ring carrier 100 may be formed in a triangular shape so that the ring carrier 100 may be easily put down or lifted, and weight thereof may be reduced at the same time.

Meanwhile, the above-described ring carrier 100 and a ring transport system including the ring carrier 100 may be configured in a plasma processing facility.

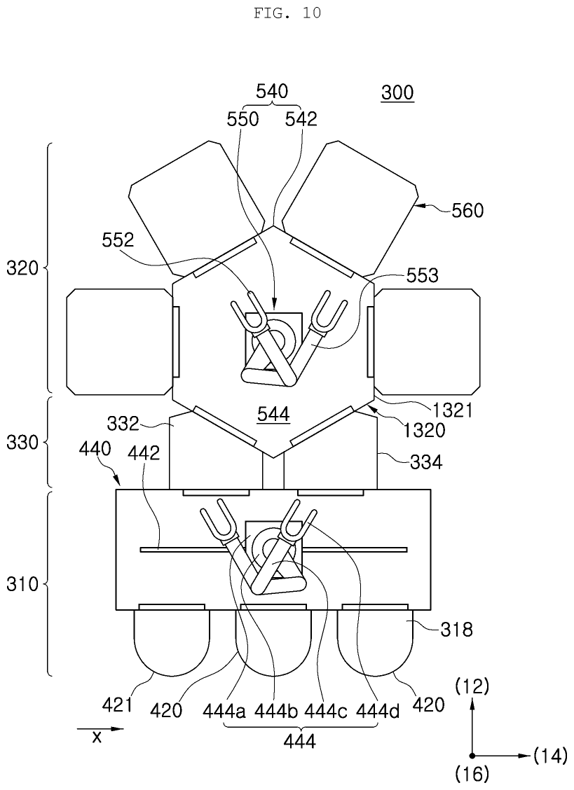

FIG. 10 is a plan view illustrating a plasma processing facility 300 according to an embodiment of the present disclosure.

Referring to FIG. 10, the plasma processing facility 300 includes an index module 310, a load lock module 330, and a process module 320. The index module 310 includes a load port 420 and a transport frame 440. The load port 420, the transport frame 440, and the process module 320 are sequentially arranged in a line. Hereinafter, a direction in which the load port 420, the transport frame 440, the load lock module 330, and the process module 320 are arranged is referred to as a first direction 12, a direction perpendicular to the first direction 12 when viewed from above is referred to as a second direction 14, and a direction perpendicular to the plane including the first direction 12 and the second direction 14 is referred to as a third direction 16.

In the present invention, the load lock module 330 and the process module 320 are collectively referred to as a processing module.

A cassette 318 in which a plurality of substrates W are accommodated is seated in the load port 420. A plurality of load ports 420 are provided, and the load ports 420 are arranged in a line along the second direction 14. FIG. 10 shows that two load ports 420 and one carrier storage unit 421 are provided. However, the number of load ports 420 may increase or decrease according to conditions such as process efficiency of the process module 320 and footprints. The cassette 318 has a slot (not shown) provided to support the edges of the substrate. A plurality of slots are provided in the third direction 16, and the substrates are positioned in the cassette 318 to be stacked while being spaced apart from each other along the third direction 16. A front opening unified pod (FOUP) may be used as the cassette 318.

The carrier storage unit 421 may be provided in the index module 310. The carrier storage unit 421 is a unit in which a carrier on which a ring member (ring R) is placed is stored when the ring member is transported into a chamber using a hand. The outer shape of the carrier storage unit 421 may be provided similar to that of the cassette 318. The interior of the carrier storage unit 421 may also be provided similarly to the interior of the cassette 318.

In the transport frame 440 provided with one or more load ports 420 into which the cassettes 318 are placed in the index module 310, and an index robot that transports substrates between the cassette 318 placed in the load port 420 and the processing module, the load ports 420 and the transport frame 440 may be arranged in a first direction, and the load ports 420 and the carrier storage unit 421 may be arranged in the same direction as the first direction 12 when viewed from above.

As shown in FIG. 10, the carrier storage unit 421 and the load ports 420 are arranged side by side. According to FIG. 10, the carrier storage unit 421 is shown to be disposed at the edge, but may also be disposed between the load ports 420. That is, the carrier storage unit 421 may be placed anywhere where the load port 420 may be placed.

In another embodiment, the carrier storage unit 421 may be arranged in the second direction 14 perpendicular to the first direction 12 when viewed from above. The carrier storage unit 421 may be disposed on one side of the transport frame 440 other than the side on which the load ports 420 are disposed. According to another embodiment, the carrier storage unit 421 may be provided at a location spaced apart from the processing module 320/330 and the index module 310. When the carrier storage unit 421 is provided at a location spaced apart from the processing module 320/330 and the index module 310, the carrier storage unit 421 may be transported into the index module 310 using a separate transport system (a component transport system for semiconductor manufacturing).

The transport frame 440 transports the substrate W between the cassette 318 seated in the load port 420 and the load lock module 330. An index rail 442 and an index robot 444 are provided on the transport frame 440. The length direction of the index rail 442 is parallel to the second direction 14. The index robot 444 is installed on the index rail 442 and linearly moves in the second direction 14 along the index rail 442. The index robot 444 has a base 444a, a body 444b, and an index arm 444c and a hand 144d. The base 444a is installed to be movable along the index rail 442. The body 444b is coupled to the base 444a. The body 444b is provided to be movable along the third direction 16 on the base 444a. In addition, the body 444b is provided to be rotatable on the base 444a. The index arm 444c is coupled to the body 444b and is provided to be movable forward and backward with respect to the body 444b. A plurality of index aims 444c are provided to be individually driven. The index arms 444c are stacked and spaced apart from each other along the third direction 16. Some of the index arms 444c may be used when transferring the substrate W from the process module 320 to the cassette 318, and the rest of the index arms 444c may be used when transferring the substrate W from the cassette 318 to the process module 320. This may prevent particles generated from the pre-processed substrate W from being attached to the post-processed substrate W during the process of carrying in and taking out the substrate W by the index robot 444.

The load lock module 330 is disposed between the transport frame 440 and a transport unit 540. The load lock module 330 replaces a normal pressure atmosphere of the index module 310 with a vacuum atmosphere of the process module 320 for the substrate W carried into the process module 320, or replaces the vacuum atmosphere of the process module 320 with the normal pressure atmosphere of the index module 310 for the substrate W carried out to the index module 310. The load lock module 330 provides a processing space 110b where the substrate W stays before being transferred between the transport unit 540 and the transport frame 440. The load lock module 330 includes a load lock chamber 332 and an unload lock chamber 334.

The substrate W transported from the index module 310 to the process module 320 temporarily stays in the load lock chamber 332. The load lock chamber 332 maintains a normal pressure atmosphere in a stand-by state, and remains open to the index module 310 while being blocked to the process module 320. When the substrate W is loaded into the load lock chamber 332, the internal space is sealed for each of the index module 310 and the process module 320. Thereafter, the atmosphere of the internal space of the load lock chamber 332 is replaced from normal pressure to vacuum, and is opened to the process module 320 while being blocked from the index module 310.

In the unload lock chamber 334, the substrate W transferred from the process module 320 to the index module 310 temporarily stays. The unload lock chamber 334 maintains a vacuum atmosphere in a stand-by state, and remains open to the process module 320 while being blocked to the index module 310. When the substrate W is loaded into the unload lock chamber 334, the internal space is sealed for each of the index module 310 and the process module 320. Thereafter, the atmosphere of the internal space of the unload lock chamber 334 is replaced from vacuum to normal pressure, and is opened to the index module 310 while being blocked from the process module 320.

The process module 320 includes the transport unit 540 and a plurality of process chambers 560.

The transport unit 540 transfers the substrate W between the load lock chamber 332, the unload lock chamber 334, and the plurality of process chambers 560. The transport unit 540 includes a transport chamber 542 and a transport robot 550. The transport chamber 542 may be provided in a hexagonal shape. Optionally, the transport chamber 542 may be provided in a rectangular or pentagonal shape. Around the transport chamber 542, the load lock chamber 332, the unload lock chamber 334, and the plurality of process chambers 560 are positioned. Inside the transport chamber 542, a transport space 544 for transferring the substrate W is provided.

The transport robot 550 transports the substrate W in the transport space 544. The transport robot 550 may be located in the center of the transport chamber 542. The transport robot 550 may move in horizontal and vertical directions, and may have a plurality of transport hands 552 capable of moving forward, backward, or rotating on a horizontal plane. Each transport hand 552 may be operated independently, and the substrate W may be placed on the transport hand 552 in a horizontal state.

The transport robot 550 may include the transport hand 552 capable of seating a substrate and a transport arm 553. A robot body (not shown) has a drive means such as a stepping motor therein, and controls the operation of the transport arm 553. The transport arm 553 may perform an unfolding or folding operation to transport the substrate W by receiving power from the robot body (not shown), and may also perform an upward or downward movement. The transport arm 553 may be provided in various shapes. The transport hand 200 and the transport arm A shown in FIG. 6 may be applied to the transport hand 552 and the transport arm 553 shown in FIG. 10, respectively.

In an embodiment, the transport hand 552 may be provided in a Y-shape connected to the front end of the transport arm 553 so as to easily receive and hand over the substrate and other members to other configurations. In this embodiment, the shape of the transport hand 552 has been shown and described as a “Y” shape, but the shape of the transport hand 552 may be changed and provided in various forms such as an “I” shape.

The process chamber 560 performs a process of treating a substrate with plasma. According to an example, the substrate treatment process may be an etching process. Alternatively, the process performed in the process chamber 560 may be a process of treating a substrate using a gas other than plasma.

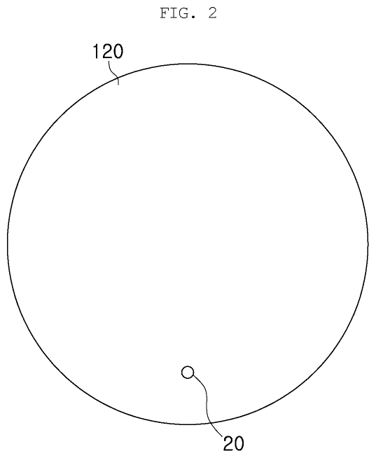

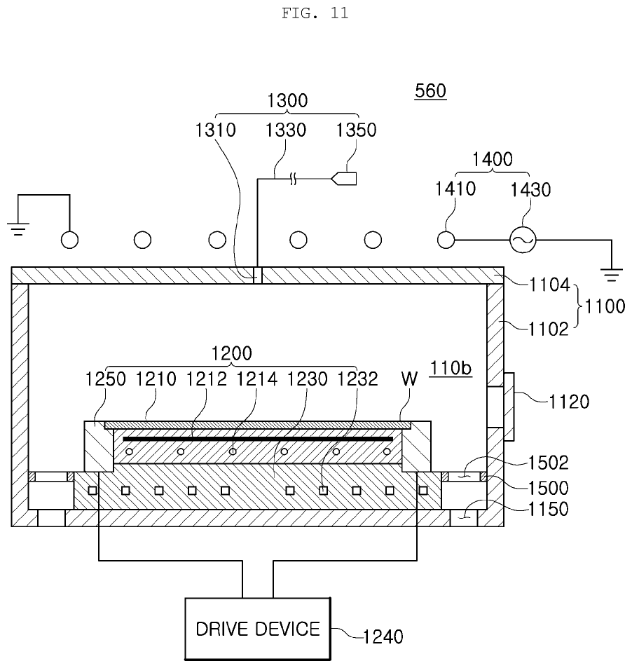

FIG. 11 is a cross-sectional view illustrating the process chamber 560 of FIG. 10. Referring to FIG. 2, the process chamber includes a housing 1100, a substrate support unit 1200, a gas supply unit 1300, a plasma source 1400, and an exhaust baffle 1500.

The housing 1100 has a processing space 1106 in which the substrate W is processed. The housing 1100 is provided in a tubular shape. The housing 1100 is made of a metal material. For example, the housing 1100 may be made of aluminum. An opening is formed in one side wall of the housing 1100. The opening functions as an entrance through which the substrate W is carried in and out. The opening is opened and closed by a door 1120. A lower hole 1150 is formed through the bottom surface of the housing 1100. The lower hole 1150 is connected to a pressure reducing member (not shown). Removing air from the processing space 1106 of the housing 1100 is performed by the pressure reducing member, and a reduced pressure atmosphere may be formed.

The substrate support unit 1200 supports the substrate W in the processing space 1106. The substrate support unit 1200 may be provided as an electrostatic chuck 1200 that supports the substrate W using electrostatic force. Optionally, the substrate support unit 1200 may support the substrate W in various ways such as mechanical clamping.

The substrate support unit 1200 includes a dielectric plate 1210, a base 1230, and a focus ring 1250. The dielectric plate 1210 is provided as a dielectric plate 1210 including a dielectric material. The substrate W is directly placed on the upper surface of the dielectric plate 1210. The dielectric plate 1210 is provided in a disk shape. The dielectric plate 1210 may have a smaller radius than the substrate W. Inside the dielectric plate 1210, an internal electrode 1212 is installed. A power source (not shown) is connected to the internal electrode 1212 and receives power from the power source (not shown). The internal electrode 1212 provides electrostatic force based on applied electric power (not shown) so that the substrate W is adsorbed to the dielectric plate 1210. A heater 1214 for heating the substrate W is installed inside the dielectric plate 1210. The heater 1214 may be positioned below the internal electrode 1212. The heater 1214 may be provided as a spiral coil.

The base 1230 supports the dielectric plate 1210. The base 1230 is positioned below the dielectric plate 1210 and is fixedly coupled with the dielectric plate 1210. The upper surface of the base 1230 has a stepped shape such that the center area is higher than the edge area. The base 1230 has the central area of the upper surface corresponding to the bottom surface of the dielectric plate 1210. A cooling passage 1232 is formed inside the base 1230. The cooling passage 1232 is provided as a path through which cooling fluid circulates. The cooling passage 1232 may be provided in a spiral shape inside the base 1230. The base is connected to a high frequency power source 1234 located outside. The high frequency power source 1234 applies power to the base 1230. Power applied to the base 1230 guides the plasma generated in the housing 1100 to move toward the base 1230. The base 1230 may be made of a metal material. When processing a substrate in the processing unit, one or more focus rings 1250 are provided around the substrate.

The focus ring 1250 may correspond to the ring R carried by the ring carrier 100 described in the present disclosure.

The focus ring 1250 focuses the plasma onto the substrate W. The focus ring 1250 focuses the plasma onto the substrate W. The focus ring 1250 is provided in a ring shape and is disposed along the circumference of the dielectric plate 1210. An upper surface of the focus ring 1250 may be stepped so that an inner portion adjacent to the dielectric plate 1210 is lower than an outer portion. The inner portion of the upper surface of the focus ring 1250 may be positioned at the same height as the central region of an upper surface of the dielectric plate 1210. The inner portion of the upper surface of the focus ring 1250 supports an edge region of the substrate W positioned outside the dielectric plate 1210. The focus ring 1250 expands an electric field forming region so that the substrate is positioned at the center of a region where plasma is formed.

A drive device 1240 that drives the focus ring 1250 may be connected to the focus ring 1250. When replacement of the focus ring 1250 is required, the drive device 1240 may drive the focus ring 1250 to move up and down. The drive device 1240 may include a pin structure (not shown) for lifting and lowering the focus ring. When replacement of the focus ring 1250 is required, the focus ring 1250 is lifted and lowered by a pin (not shown) included in the drive device 1240. When the focus ring 1250 is lifted, the hand 144d is inserted into the bottom of the focus ring to receive the focus ring from the pin (not shown).

The gas supply unit 1300 supplies a process gas onto the substrate W supported by the substrate support unit 1200. The gas supply unit 1300 includes a gas storage part 1350, a gas supply line 1330, and a gas inlet port 1310. The gas supply line 1330 connects the gas storage part 1350 and the gas inlet port 1310. The process gas stored in the gas storage part 1350 is supplied to the gas inlet port 1310 through the gas supply line 1330. The gas inlet port 1310 is installed on the upper wall of the housing 1100. The gas inlet port 1310 is positioned opposite to the substrate support unit 1200. According to an example, the gas inlet port 1310 may be installed at the center of the upper wall of the housing 1100. A valve may be installed in the gas supply line 1330 to open or close the inner passage or to adjust the flow rate of gas flowing through the inner passage. For example, the processing gas may be an etching gas.

The plasma source 1400 excites the processing gas in the housing 1100 into a plasma state. As the plasma source 1400, an inductively coupled plasma (ICP) source may be used. The plasma source 1400 includes an antenna 1410 and an external power source 1430. The antenna 1410 is disposed on the outer upper portion of the housing 1100. The antenna 1410 is provided in a spiral shape that is wound multiple times and is connected to the external power source 1430. The antenna 1410 receives power from the external power source 1430. The antenna 1410 to which power is applied forms a discharge space in the internal space of the housing 1100. The process gas staying in the discharge space may be excited into a plasma state.

The exhaust baffle 1500 uniformly exhausts the plasma for each area in the processing space 1106. The exhaust baffle 1500 has an annular ring shape. The exhaust baffle 1500 is positioned between the substrate support unit 1200 and the inner wall of the housing 1100 in the processing space 1106. A plurality of exhaust holes 1502 are formed in the exhaust baffle 1500. The exhaust holes 1502 are provided to face up and down. The exhaust holes 1502 are provided as holes extending from the top to the bottom of the exhaust baffle 1500. The exhaust holes 1502 are spaced apart from each other along the circumferential direction of the exhaust baffle 1500. Each exhaust hole 1502 has a slit shape and has a longitudinal direction toward the radial direction.

According to an embodiment of the present disclosure, when the index robot 444 or the transport robot 550 transports the focus ring 1250, both robots may transport the ring using the carrier 1600. However, according to another embodiment, the carrier 1600 is used when the index robot 444 transports the focus ring 1250, and is not used when the transport robot 550 transports the focus ring 1250. In the latter embodiment, the transport arm 553 may be modified so that the transport robot 550 may be used to transfer both the ring member and the substrate, and the ring member may be placed on a pad on the transport arm 553 and transported without a carrier. According to the latter embodiment, the carrier 1600 may be used to transport the ring member from the carrier storage unit 421 to the load lock module 330, and may not be used in the process of transporting the ring member from the load lock module 330 to the process chamber 560.

The plasma processing facility 300 includes: the process chamber 560 in which plasma treatment is performed on a substrate W; and the transport robot 550 including the transport hand 552 that transfers the substrate W to the process chamber 560 and supports the substrate W from the bottom, and the transport arm 553 that drives the transport hand 552.

The process chamber 560 includes: the housing 1100 having the processing space 110b therein; the substrate support unit 1200 supporting a substrate W in the processing space 110b; the gas supply unit 1300 supplying process gas to the processing space 110b; and the plasma source 1400 generating plasma from the process gas.

The substrate support unit 1200 is provided to surround the dielectric plate 1210 on which a substrate W is placed and the substrate W placed on the dielectric plate 1210, and includes the focus ring 1250 provided detachably from the dielectric plate 1210.

The focus ring 1250 is coupled to the ring carrier 100 and transported by the transport robot 550. The lower surface 120 of the ring carrier 100 is in contact with the transport hand 552, and on the upper surface 110 of the ring carrier 100, the ring support pad 130 generating frictional force with the focus ring 1250 is installed to come into contact with the focus ring 1250.

The ring carrier 100 includes: the first vacuum hole 10 formed through the upper surface 110; the second vacuum hole 20 formed through the lower surface; and the air passage 30 provided between the first vacuum hole 10 and the second vacuum hole 20.

In the previously described embodiment, the ring carrier was described as an example of a component carrier. However, the scope of rights of the present disclosure is not limited to the ring carrier, and it should be seen as extending to the component carrier for a component that needs to be transported using a medium called a carrier because it is difficult to transport the component directly by the transport hand due to the shape of the component, such as the shape with a through-hole or groove in the upward direction.

In the above, specific details for carrying out the present disclosure have been provided by describing the embodiments of the present disclosure. However, the technical spirit of the present disclosure is not limited to the described embodiments, and may be embodied in various forms within the scope not contrary to the technical spirit of the present disclosure.

What is claimed is:

1. A component carrier for semiconductor manufacturing that transports components while a lower surface thereof is in contact with a transport hand and an upper surface thereof is in contact with a component for semiconductor manufacturing, the carrier comprising:
a first vacuum hole formed through the upper surface;
a second vacuum hole formed through the lower surface; and
an air passage provided between the first vacuum hole and the second vacuum hole.

2. The component carrier for semiconductor manufacturing of claim 1, further comprising:
a component support pad configured to include a through hole installed on the upper surface to generate frictional force with component part and communicate with the first vacuum hole,
wherein the first vacuum hole is formed in a portion where the component support pad is installed.

3. The component carrier for semiconductor manufacturing of claim 2, wherein the first vacuum hole is provided in plural.

4. The component carrier for semiconductor manufacturing of claim 3, wherein one second vacuum hole is provided.

5. The component carrier for semiconductor manufacturing of claim 1, wherein the second vacuum hole is provided at a position capable of communicating with a vacuum hole formed in the transport hand.

6. The component carrier for semiconductor manufacturing of claim 5, further comprising:
a component support pad configured to include a through hole installed on the upper surface to generate frictional force with component part and communicate with the first vacuum hole,
wherein the first vacuum hole is formed in a portion where the component support pad is installed.

7. The component carrier for semiconductor manufacturing of claim 6, wherein the first vacuum hole is provided in plural.

8. The component carrier for semiconductor manufacturing of claim 7, wherein one second vacuum hole is provided.

9. The component carrier for semiconductor manufacturing of claim 3, wherein the air passage connects the second vacuum hole and the first vacuum hole with each other.

10. The component carrier for semiconductor manufacturing of claim 3, wherein the air passage comprises:
a first air passage configured to connect the second vacuum hole to any one of the first vacuum holes; and
a second air passage configured to connect all of the first vacuum holes with each other.

11. The component carrier for semiconductor manufacturing of claim 6, wherein the air passage connects the second vacuum hole and the first vacuum hole with each other.

12. The component carrier for semiconductor manufacturing of claim 6, wherein the air passage comprises:
a first air passage configured to connect the second vacuum hole to any one of the first vacuum holes; and
a second air passage configured to connect all of the first vacuum holes with each other.

13. A component transport system for semiconductor manufacturing, the system comprising:
a component carrier for semiconductor manufacturing configured to transport a component while in contact with the component;
a transport hand configured to contact a lower surface of the component carrier for semiconductor manufacturing; and
a transport arm configured to drive the transport hand,
wherein the component carrier for semiconductor manufacturing comprises:
a first vacuum hole formed through an upper surface thereof;
a second vacuum hole formed through the lower surface thereof; and
an air passage provided between the first vacuum hole and the second vacuum hole.

14. The component transport system for semiconductor manufacturing of claim 13, further comprising:
a component support pad configured to include a through hole installed on the upper surface to generate frictional force with component part and communicate with the first vacuum hole,
wherein the first vacuum hole is formed in a portion where the component support pad is installed.

15. The component transport system for semiconductor manufacturing of claim 14, wherein the first vacuum hole is provided in plural and one second vacuum hole is provided.

16. The component transport system for semiconductor manufacturing of claim 13, wherein the second vacuum hole is provided at a position capable of communicating with a vacuum hole formed in the transport hand.

17. The component transport system for semiconductor manufacturing of claim 16, wherein a friction pad including a through hole having a larger cross-sectional area than the vacuum hole is provided on an upper part of the vacuum hole formed in the transport hand, and the second vacuum hole communicates with the through hole of the friction pad.

18. The component transport system for semiconductor manufacturing of claim 17, wherein the first vacuum hole is provided in plural and one second vacuum hole is provided.

19. The component transport system for semiconductor manufacturing of claim 18, wherein the air passage connects the second vacuum hole and the first vacuum hole with each other.

20. A plasma processing facility, comprising:
a process chamber in which plasma treatment is performed on a substrate; and
a transport robot configured to transport the substrate to the process chamber, and include a transport hand for supporting the substrate from a bottom and a transport arm for driving the transport hand,
wherein the process chamber comprises:
a housing having a processing space therein;
a support unit supporting the substrate in the processing space;
a gas supply unit supplying a process gas to the processing space; and
a plasma source generating plasma from the process gas,
wherein the support unit comprises:
an electrostatic chuck on which the substrate is placed; and
a focus ring provided to surround the substrate placed on the electrostatic chuck, and detachably provided from the electrostatic chuck,
wherein the focus ring is coupled to a component carrier for semiconductor manufacturing and transported by the transport robot,
wherein the component carrier for semiconductor manufacturing is configured such that a lower surface thereof is in contact with the transport hand, and on an upper surface thereof, a ring support pad generating frictional force with the focus ring is installed to come into contact with the focus ring, and comprises:
a first vacuum hole formed through the upper surface;
a second vacuum hole formed through the lower surface; and
an air passage provided between the first vacuum hole and the second vacuum hole.
